(19) United States
(12) Patent Application Publication
(10) Pub. No.: US 2007/0117535 A1
(43) Pub. Date: May 24, 2007

(54) Multifunctional radio

(75) Inventors: Tzu-Cheng Yu, Fremont, CA (US); Ming-Ling Chen, Tu-Cheng (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: HON HAI Precision Industry CO., LTD., Tu-Cheng City (TW)

(21) Appl. No.: 11/501,955

(22) Filed: Aug. 10, 2006

(30) Foreign Application Priority Data
Nov. 18, 2005 (CN) 200520067943.2

(51) Int. Cl. H05K 11/00

(52) U.S. Cl. 455/344; 455/347

(57) ABSTRACT

A multifunctional radio (100) includes a housing (10) and at least one speaker (16). The housing has an external interface (144) for connecting an external device. The at least one speaker is fixed in the housing. The at least one speaker is electronically adapted by the external device. The multifunctional radio may be connected with an MP3 player device. Therefore, the MP3 player may transform an electronic signal into sound by means of the speakers of the multifunctional radio.

### BACKGROUND OF THE INVENTION

1. FIELD OF THE INVENTION

The present invention generally relates to radios and, particularly, to a multifunctional radio which may play external devices.

2. DISCUSSION OF THE RELATED ART

Radios are receiving equipments of wireless broadcast system. Numerous popular radio devices, such as AM/FM radios, utilize radio frequency receivers to detect and reproduce sounds from radio frequency signals transmitted by distant broadcasting stations. These receivers are generally tuned to select one of a number of stations by setting the resonant frequency of an oscillator in the receiver to a frequency that differs from the frequency of the signal transmitted from other stations by a predetermined fixed amount. Accordingly, people may freely choose any station to listen, thereby making life rich and colorful.

Radios are adored by a wide range of consumers owing to a broad selection of entertainment programs. However, a typical radio cannot connect with an external device such as an MPEG Audio Laye-3 (MP3) player so as to provide a strong amplifier for the sound from the MP3 player. Accordingly, conventional radios are often difficult to satisfy needs of consumers.

Although MP3 players may have a FM radio function, the radio function is a secondary function making the receiving range and precision not as good as a common radio. Furthermore, the volume of MP3 player products is limited such that MP3 player products usually have a weak amplifier.

Therefore, a new multifunctional radio is desired in order to overcome the above-described shortcomings.

### SUMMARY

In one embodiment thereof, a multifunctional radio includes a housing and at least one speaker. The housing has an external interface configured for connecting an external device. The at least one speaker is fixed to the housing. The at least one speaker is electrically adapted by the external device.

Other advantages and novel features will become more apparent from the following detailed description when taken in conjunction with the accompanying drawing.

### BRIEF DESCRIPTION OF THE DRAWINGS

Many aspects of the multifunctional radio can be better understood with reference to the following drawing. The components in the drawing are not necessarily drawn to scale, the emphasis instead being placed upon clearly illustrating the principles of the multifunctional radio. Moreover, in the drawings, like reference numerals designate corresponding parts throughout the several views.

FIG. 1 is an isometric view of an embodiment of the multifunctional radio.

### DETAILED DESCRIPTION OF THE EMBODIMENTS

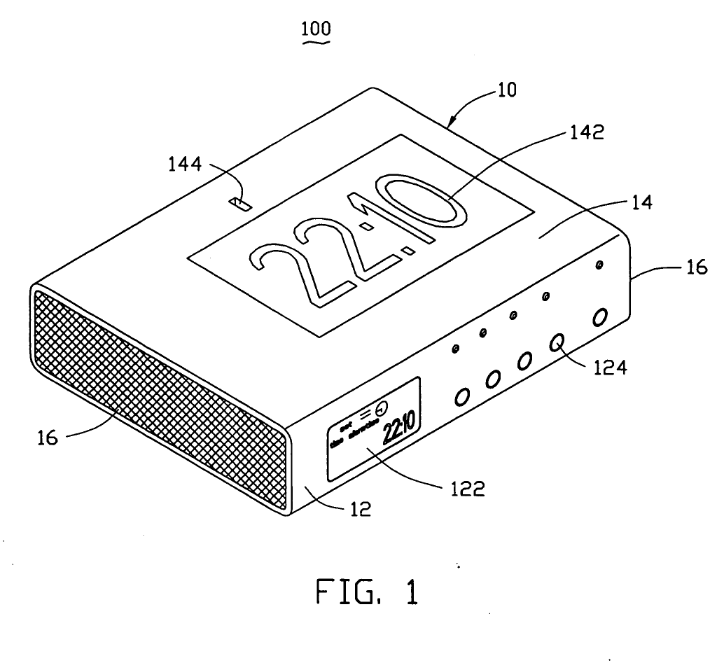

Referring to drawings in detail, FIG. 1 shows a multifunctional radio 100 in accordance with a first embodiment of the present invention. The multifunctional radio 100 includes a housing 10 and a printed circuit board (not shown) received therein.

The housing 10 is substantially rectangular, and includes a front surface 12 and a top surface 14. The front surface 12 is oriented perpendicular to the top surface 14. A display 122 is located on the front surface 12. A number of function buttons 124 are arranged on the left side surface 12 adjacent to the display 122 for operating the multifunctional radio 100.

The display 122 is used to display information that includes a digital dial to show the radio station setting tuned-in, and may also show a current state such as a sleep state or an alarm state. A subsidiary display 142 is disposed on the top surface 14 by way of digital type. The subsidiary display 142 functions as a time display to show a time that is large enough in size and relatively easy to see. The subsidiary display 142 may be a liquid crystal display (LED) display screen or an electroluminescent display screen configured for displaying time. Accordingly, the subsidiary display 142 may illuminate in the dark.

The housing 10 has two speakers. 16 disposed at two ends thereof so as to transform an electronic signals into sound. A universal serial bus (USB) interface 144 is disposed at the top surface 14 adjacent to the subsidiary display 142. A typical MP3 player may be inserted in the interface 144 so as to connect with the multifunctional radio 100. Accordingly, the MP3 player may transform its electronic signals into sounds by means of the speakers 16 of the multifunctional radio 100.

The printed circuit board includes a radio module configured for receiving AM/FM radio signals. The multifunctional radio 100 may play both AM/FM radio stations and broadcast TV bands. The radio module electrically connected to the speakers 16 so as to enable the speakers 16 to transform the AM/FM radio signals into sound. The multifunctional radio 100 includes an alarm system for setting alarms for a full week, weekdays, or the weekend. The alarm system includes an alarm clock circuit that is electrically coupled to the radio output circuit. The alarm clock circuit has an alarm output signal. The radio output circuit is responsive to the alarm output signal of the alarm clock circuit in a manner so as to output an alarm signal. The alarm signal is sent to a device such as a buzzer, a bell, or other transducer.

In operation, the user of the radio 100 actuates one or more of several buttons disposed on the housing 10 to operate the radio receiver mode and clock functions. When the user desires to place the clock in an alarm mode, such as to wake up at a predetermined time, he actuates the appropriate buttons 124 to set the alarm time and to place the alarm in an “armed” state. When the actual time is reached, the bell device is actuated to emit a sound that will notify, or wake, the user.

In another embodiment, the USB interface 144 is replaced with an IEEE1394 external interface.

In the above-mentioned embodiments, the interface 144 acts as a connecting interface configured for connecting an external device and allows the external device to transmit an electronic signal to the speaker so as to transform into sound.

As described above, the preferred embodiments provides the multifunctional radio convenient for a user to connect the MP3 player by way of the external device. It is, however, to be understood that the multifunctional radio could potentially be useful in other applications in which it may be desirable to connect other devices.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

We claim:

1. A multifunctional radio comprising:
a housing, the housing having an external interface configured for connecting an external device; and
at least one speaker fixing in the housing, the at least one speaker electrically adapted by the external device.

2. The multifunctional radio as claimed in claim 1, wherein the multifunctional radio includes a front surface and a top surface, the front surface has a display and a plurality of buttons, and the external interface is defined on the top surface.

3. The multifunctional radio as claimed in claim 2, wherein the top surface has a subsidiary display adjacent to the external interface.

4. The multifunctional radio as claimed in claim 3, wherein the subsidiary display is a liquid crystal display screen.

5. The multifunctional radio as claimed in claim 3, wherein the subsidiary display is an electroluminescent display screen.

6. The multifunctional radio as claimed in claim 1, wherein the at least one speaker includes two speakers, and the two speakers are disposed at two ends of the multifunctional radio.

7. The multifunctional radio as claimed in claim 1, wherein the external device is a MP3 playing device.

8. The multifunctional radio as claimed in claim 1, wherein the multifunctional radio includes an alarm system and a radio output circuit, the alarm system includes an alarm clock circuit, which is electrically coupled to the radio output circuit.

9. The multifunctional radio as claimed in claim 1, wherein the external interface is a universal serial bus interface.

10. The multifunctional radio as claimed in claim 1, wherein the external interface is an IEEE1394 external interface.

11. A multifunctional radio comprising:
at least one speaker, the at least one speaker electrically configured for an external device; the external device transforming an electronic signal into sound by means of the at least one speaker.

12. The multifunctional radio as claimed in claim 11, further comprising an external interface, the external interface is connectable with the external device.

13. The multifunctional radio as claimed in claim 12, wherein the external interface is a universal serial bus interface.

14. The multifunctional radio as claimed in claim 12, wherein the external interface is an IEEE1394 external interface.

15. A multifunctional radio comprising:
a speaker;
an electrical circuit including a radio module configured for receiving AM/FM radio signals, the radio module electrically connected to the speaker so as to enable the speaker to transform the Am/Fm radio signals into sound; and
the electrical circuit including a connecting interface configured for connecting an external device and allowing the external device to transmit an electronic signal to the speaker to transform into sound.
